(19) United States
(12) Patent Application Publication
(10) Pub. No.: US 2026/0239867 A1
(43) Pub. Date: Aug. 13, 2026

(54) METHOD OF FORMING COATING LAYER ON INKJET HEAD AND METHOD OF EJECTING INK USING THE INKJET HEAD

(71) Applicant: Samsung Display Co., Ltd., Yongin-si (KR)

(72) Inventors: BYEONGJUN LEE, Yongin-si (KR); JAESIK KIM, Yongin-si (KR); JUNGHAN SEO, Yongin-si (KR); WOO YONG SUNG, Yongin-si (KR); SEUNGHO YOON, Yongin-si (KR)

(21) Appl. No.: 19/360,772

(22) Filed: Oct. 16, 2025

(30) Foreign Application Priority Data
Feb. 7, 2025 (KR) 10-2025-0015797

(51) Int. Cl. H10K 71/13; B41J 2/16; B41J 2/165

(52) U.S. Cl. CPC H10K 71/135; B41J 2/1606; B41J 2/164; B41J 2/16502; B41J 2/16535

(57) ABSTRACT

A method of forming a coating layer on an inkjet head may include: removing ink remaining on an ejection surface of an inkjet head, removing a first coating layer on the ejection surface of the inkjet head, and forming a second coating layer on the ejection surface of the inkjet head. The second coating layer may be formed on the ejection surface without including a step over an entire area of the ejection surface. Accordingly, ink may be ejected in a direction normal (e.g., substantially perpendicular) to the ejection surface.

### CROSS-REFERENCE TO RELATED APPLICATION

The present application claims priority to and the benefit of Korean Patent Application No. 10-2025-0015797, filed on February 07, 2025, in the Korean Intellectual Property Office, the entire content of which is incorporated herein by reference.

### BACKGROUND

### Field

One or more embodiments of the present disclosure relate to a method of forming a coating layer on an inkjet head and a method of ejecting ink utilizing the inkjet head.

### Description of the Related Art

Display devices are utilized to present (or convey) visual information to users. Among various types (kinds) of display devices, organic light emitting diode (OLED) display devices have recently gained significant attention due to their superior image quality and energy efficiency.

Such display devices may be manufactured utilizing inkjet apparatuses. For example, a color conversion layer included in a display device may be formed utilizing an inkjet apparatus. The inkjet apparatus may include inkjet head discharging ink. After the ink is ejected by the inkjet head, residual ink may remain on the ejection surface of the inkjet head. During the process of removing this residual ink, the ejection surface may be subject to damage, potentially affecting the performance and longevity of the inkjet head.

### SUMMARY

One or more aspects of embodiments of the present disclosure are directed toward a method of forming a coating layer on an inkjet head.

One or more aspects of embodiments of the present disclosure are directed toward a method of ejecting ink utilizing the inkjet head.

Additional aspects of embodiments will be set forth in part in the description which follows and, in part, will be apparent from the description or may be learned by practice of the presented embodiments of the disclosure.

A method of forming a coating layer on an inkjet head according to one or more embodiments includes removing ink remaining on an ejection surface of an inkjet head, removing a first coating layer on the ejection surface of the inkjet head, and forming a second coating layer on the ejection surface of the inkjet head.

In one or more embodiments, the removing of the ink remaining on the ejection surface of the inkjet head may include removing the ink remaining on the ejection surface of the inkjet head in a contact manner through a blotting process.

In one or more embodiments, a portion of the first coating layer on the ejection surface of the inkjet head may be removed by the blotting process.

In one or more embodiments, a first area in which the first coating layer is removed and a second area in which the first coating layer remains may be formed on the ejection surface of the inkjet head by the blotting process.

In one or more embodiments, the first coating layer remaining in the second area may be removed through the removing of the first coating layer.

In one or more embodiments, the first coating layer may include a 1-1 coating layer on the ejection surface of the inkjet head, a 1-2 coating layer on the 1-1 coating layer, and a 1-3 coating layer on the 1-2 coating layer and including a liquid-repellent material.

In one or more embodiments, the removing of the first coating layer may include removing the 1-3 coating layer through an ashing process.

In one or more embodiments, the removing of the first coating layer may further include removing the 1-1 coating layer and the 1-2 coating layer through a laser trimming process.

In one or more embodiments, a distance between a lower surface of the second coating layer and the ejection surface of the inkjet head may be substantially uniform over an entire area of the ejection surface of the inkjet head by the removing of the 1-3 coating layer through the ashing process and the removing of the 1-1 coating layer and the 1-2 coating layer through the laser trimming process.

In one or more embodiments, a first area in which the 1-1 coating layer, the 1-2 coating layer, and the 1-3 coating layer are removed on the ejection surface of the inkjet head and a second area in which the 1-1 coating layer, the 1-2 coating layer, and the 1-3 coating layer remain may be formed by the blotting process.

In one or more embodiments, the second coating layer may include a 2-1 coating layer on the ejection surface of the inkjet head and including a wear-resistant material, a 2-2 coating layer on the 2-1 coating layer, and a 2-3 coating layer on the 2-2 coating layer and including a liquid-repellent material.

In one or more embodiments, the 2-1 coating layer may include at least one selected from the group consisting of aluminum oxide (Al₂O₃), silicon carbide (SiC), titanium nitride (TiN), titanium aluminum nitride (TiAlN), and aluminum chromium nitride (AlCrN).

A method of forming a coating layer on an inkjet head according to one or more embodiments includes removing ink remaining on an ejection surface of an inkjet head through a blotting process, removing a 1-2 coating layer and a 1-3 coating layer from a first coating layer including a 1-1 coating layer on the ejection surface of the inkjet head, the 1-2 coating layer on the 1-1 coating layer, and the 1-3 coating layer on the 1-2 coating layer, and forming a second coating layer on the 1-1 coating layer.

In one or more embodiments, the removing of the 1-2 coating layer and the 1-3 coating layer from the first coating layer may include removing the 1-3 coating layer through an ashing process and removing the 1-2 coating layer through a laser trimming process, and a distance between a lower surface of the second coating layer and the ejection surface of the inkjet head may be substantially uniform over an entire area of the ejection surface of the inkjet head by the removing of the 1-3 coating layer through the ashing process and the removing of the 1-1 coating layer and the 1-2 coating layer through the laser trimming process.

A method of ejecting ink utilizing an inkjet head according to one or more embodiments includes ejecting first ink utilizing an inkjet head, removing the first ink remaining on an ejection surface of the inkjet head, removing a first coating layer on the ejection surface of the inkjet head, forming a second coating layer on the ejection surface of the inkjet head, and ejecting second ink utilizing the inkjet head.

In one or more embodiments, the removing of the first ink remaining on the ejection surface of the inkjet head may include removing the first ink remaining on the ejection surface of the inkjet head in a contact manner through a blotting process.

In one or more embodiments, a first area in which the first coating layer is removed and a second area in which the first coating layer remains may be formed on the ejection surface of the inkjet head by the blotting process.

In one or more embodiments, the first coating layer remaining in the second area may be removed through the removing of the first coating layer.

In one or more embodiments, the first coating layer may include a 1-1 coating layer on the ejection surface of the inkjet head, a 1-2 coating layer on the 1-1 coating layer, and a 1-3 coating layer on the 1-2 coating layer and including a liquid-repellent material.

In one or more embodiments, the removing of the first coating layer may include removing the 1-3 coating layer through an ashing process and removing the 1-2 coating layer through a laser trimming process.

In one or more embodiments, a distance between a lower surface of the second coating layer and the ejection surface of the inkjet head may be substantially uniform over an entire area of the ejection surface of the inkjet head by the removing of the 1-3 coating layer through the ashing process and the removing of the 1-1 coating layer and the 1-2 coating layer through the laser trimming process.

In one or more embodiments, the second ink may be ejected in a direction normal (e.g., substantially perpendicular) to the ejection surface by the removing of the 1-3 coating layer through the ashing process and the removing of the 1-1 coating layer and the 1-2 coating layer through the laser trimming process.

A method of forming a coating layer on an inkjet head according to one or more embodiments includes removing ink remaining on an ejection surface of an inkjet head, removing a first coating layer on the ejection surface of the inkjet head, and forming a second coating layer on the ejection surface of the inkjet head.

For example, the first coating layer may be completely (e.g., substantially completely) removed before the second coating layer is formed on the ejection surface. Accordingly, the second coating layer may be formed on the ejection surface without including a step over an entire area of the ejection surface. Accordingly, ink may be ejected in a direction normal (e.g., substantially perpendicular) to the ejection surface. For example, by forming the second coating layer on a uniformly (e.g., substantially uniformly) prepared ejection surface, such as one from which the first coating layer has been completely or substantially completely removed, or one on which only the 1-1 coating layer remains, the inkjet head may maintain consistent ink ejection characteristics, including stable droplet formation and ejection directionality. This uniformity in the coating structure, for example, the substantially uniform distance between the lower surface of the second coating layer and the ejection surface, is important in high-precision applications, such as display device or electronic device fabrication, where even slight deviations in ink trajectory may degrade image quality. The methods as described herein enable precise reconditioning of the inkjet head, thereby enhancing manufacturing yield, extending the operational lifespan of the inkjet head, and supporting repeatable, high-accuracy ink ejection performance.

One or more embodiments of the present disclosure provide an electronic device including a display device, wherein the display device is formed by the method as described in one or more embodiments.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a front view illustrating an inkjet head according to one or more embodiments discharging ink to a substrate.

FIG. 2 is a cross-sectional view illustrating a step (e.g., an act or a task) in which ink is ejected by the inkjet head of FIG. 1.

FIGS. 3-5 are cross-sectional views illustrating steps (e.g., acts or tasks) in which ink remaining on an ejection surface of the inkjet head of FIG. 2 is removed.

FIGS. 6-8 are cross-sectional views illustrating steps (e.g., acts or tasks) in which a first coating layer on an ejection surface of the inkjet head of FIG. 5 is removed.

FIG. 9 is a cross-sectional view illustrating a step (e.g., an act or a task) in which a second coating layer is formed on an ejection surface of the inkjet head of FIG. 8.

FIG. 10 is a cross-sectional view illustrating a step (e.g., an act or a task) in which ink is ejected by the inkjet head of FIG. 9.

FIG. 11 is a diagram schematically illustrating an ink.

FIGS. 12-14 are cross-sectional views illustrating steps (e.g., acts or tasks) in which a first coating layer on an ejection surface of the inkjet head of FIG. 5 is removed.

FIG. 15 is a cross-sectional view illustrating a step (e.g., an act or a task) in which a second coating layer is formed on an ejection surface of the inkjet head of FIG. 14.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the specification.

The terminology used herein is used to describe one or more embodiments of the present disclosure only and is not intended to limit the scope of the present disclosure.

The utilization of “may” if (e.g., when) describing embodiments of the present disclosure refers to “one or more embodiments of the present disclosure.”

In the context of the present application and unless otherwise defined, the terms "use," "using," and "used" may be considered synonymous with the terms "utilize," "utilizing," and "utilized," respectively.

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items. For example, “or” is not to be construed as an exclusive meaning, for example, “A or B” is construed to include A, B, A+B, and/or the like.

Throughout the present disclosure, the expressions, such as “at least one of,” “one of,” and “selected from,” if (e.g., when) preceding a list of elements, modify the entire list of elements and do not modify the individual elements of the list. For example, "at least one of a, b, or c," “at least one selected from among a, b, and c,” "at least one selected from among a to c," and/or the like indicates only a, only b, only c, both (e.g., simultaneously) a and b, both (e.g., simultaneously) a and c, both (e.g., simultaneously) b and c, all of a, b, and c, or variations thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

As used herein, “combination thereof” refers a mixture, a laminate, a composite, a copolymer, an alloy, a blend, a reaction product, and/or the like of the constituents.

Herein, it should be understood that the terms, such as “includes,” “including,” “has,” or “having,” are intended to designate the presence of an embodied feature, number, step, element, or a combination thereof, but it does not preclude the possibility of the presence or addition of one or more other features, number, step, element, or a combination thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the drawings, the thickness of layers, films, panels, regions, and/or the like may be exaggerated for clarity.

It will be understood that if (e.g., when) an element, such as a layer, a film, a region, or a substrate, is referred to as being “on” another element, it may be directly on the other element or intervening elements may also be present therebetween. In contrast, if (e.g., when) an element is referred to as being “directly on” another element, there are no intervening elements present therebetween.

Hereinafter, display devices in accordance with one or more embodiments of the present disclosure will be described in more detail with reference to the accompanying drawings.

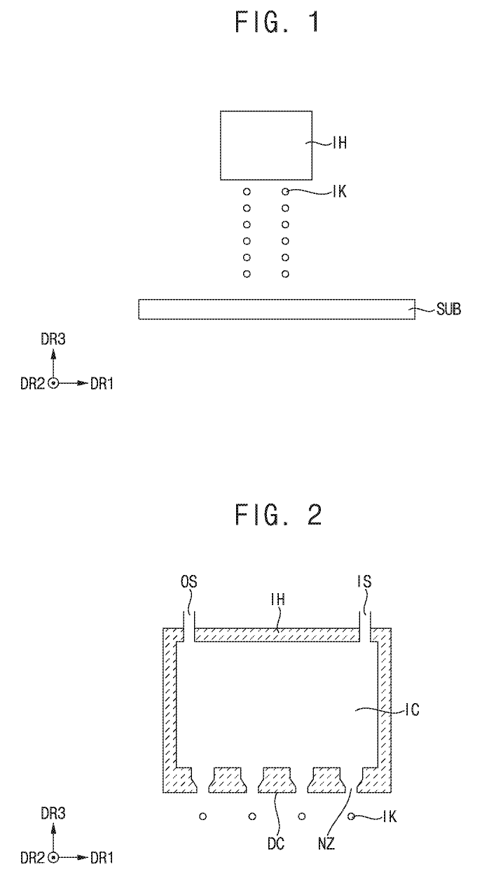

FIG. 1 is a front view illustrating an inkjet head according to one or more embodiments discharging ink to a substrate.

Referring to FIG. 1, an inkjet head IH according to one or more embodiments may be a component in an inkjet apparatus. The inkjet apparatus may be an apparatus to eject ink IK onto a target object. For example, the inkjet apparatus may be an apparatus to eject ink IK onto a substrate SUB. The inkjet head IH may be a component to eject ink IK. For example, the ink IK may be ejected onto the substrate SUB by the inkjet head IH. For example, the ink IK may be ejected onto the substrate SUB in a first direction DR1 and a second direction DR2 crossing the first direction DR1 by the inkjet head IH.

The substrate SUB may be a component in a display device. The display device may be a device to be activated by an electrical signal. For example, the display device may be a small display device utilized in compact electronic devices, such as smartphones, mobile phones, smartwatches, game consoles, cameras, and/or the like. However, embodiments of the present disclosure are not limited thereto, and the display device may also be a medium-sized display device or a large-sized display device utilized in a medium-sized electronic device or a large-sized electronic device, such as laptops, tablets, PCs, televisions, computer monitors, vehicle monitors, outdoor billboards, and/or the like.

In one or more embodiments, the display device may be an organic light-emitting display device. However, embodiments of the present disclosure are not limited thereto, and the display device may be a plasma display device, a micro light-emitting display device, a quantum dot light-emitting display device, and/or the like.

In one or more embodiments, the first direction DR1 and the second direction DR2 crossing the first direction DR1 may be defined. For example, the second direction DR2 may be normal (e.g., substantially perpendicular) to the first direction DR1. However, embodiments of the present disclosure are not limited thereto, and the second direction DR2 may form an acute angle or an obtuse angle with the first direction DR1. In one or more embodiments, a third direction DR3 crossing a plane formed by the first direction DR1 and the second direction DR2 may be defined. For example, the third direction DR3 may be normal (e.g., substantially perpendicular) to the plane formed by the first direction DR1 and the second directions DR2. However, embodiments of the present disclosure are not limited thereto, and the third direction DR3 may form an acute angle or an obtuse angle with the plane formed by the first direction DR1 and the second direction DR2.

FIG. 2 is a cross-sectional view illustrating a step (e.g., an act or a task) in which ink is ejected by the inkjet head of FIG. 1.

Referring to FIG. 2, the inkjet head IH according to one or more embodiments may include an ejection surface DC, a plurality of nozzles NZ, an ink chamber IC, an inlet IS, and an outlet OS.

The inlet IS and the outlet OS may be located or arranged at an upper portion of the inkjet head IH. For example, the inlet IS may be located or arranged at one side of the upper portion of the inkjet head IH, and the outlet OS may be located or arranged at other side of the upper portion of the inkjet head IH. The inlet IS and the outlet OS may be in communication with the ink chamber IC. Ink IK may be introduced into the ink chamber IC through the inlet IS. Ink IK that is not ejected through the plurality of nozzles NZ may be ejected to an outside of the inkjet head IH through the outlet OS. In one or more embodiments, the inlet IS and the outlet OS may extend in the third direction DR3, but embodiments of the present disclosure are not limited thereto.

Each of the plurality of nozzles NZ may be in communication with the ink chamber IC. Each of the plurality of nozzles NZ may be to eject the ink IK supplied from the ink chamber IC to the outside of the inkjet head IH. For example, each of the plurality of nozzles NZ may be to eject the ink IK onto the substrate (e.g., the substrate SUB of FIG. 1). In one or more embodiments, the plurality of nozzles NZ may be arranged in a single row. For example, as illustrated in FIG. 2, the plurality of nozzles NZ may be arranged in a single row extending in the first direction DR1. However, embodiments of the present disclosure are not limited thereto. In one or more embodiments, the plurality of nozzles NZ may be arranged in two or more rows extending in the first direction DR1. In one or more embodiments, the plurality of nozzles NZ may be arranged in a single row extending in the second direction DR2. In one or more embodiments, the plurality of nozzles NZ may be arranged in two or more rows extending in the second direction DR2.

The ejection surface DC may be a surface from which the ink IK is ejected. For example, the ejection surface DC may be a lower surface of the inkjet head IH. The ejection surface DC may be opposite to (e.g., face) the substrate. The ejection surface DC may include a plurality of holes exposing the plurality of nozzles NZ. The plurality of holes may correspond one-to-one with the plurality of nozzles NZ. Each of the holes may be in communication with a corresponding one of the plurality of nozzles NZ. The ink IK may be ejected onto the substrate through the holes and the plurality of nozzles NZ.

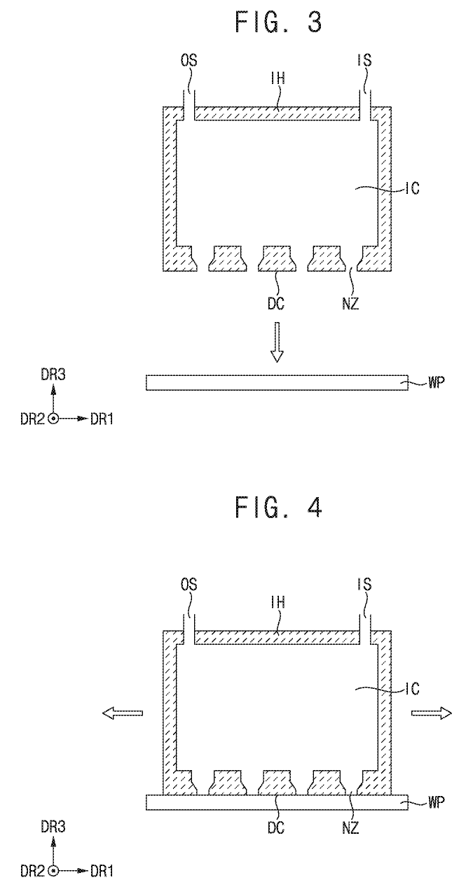

FIGS. 3, 4, and 5 are cross-sectional views illustrating steps (e.g., acts or tasks) in which ink remaining on an ejection surface of the inkjet head of FIG. 2 is removed.

Referring to FIGS. 3, 4, and 5, if (e.g., when) the ink (e.g., the ink IK of FIG. 2) is ejected to the outside of the inkjet head IH through the plurality of nozzles NZ, a portion of the ink may remain on the ejection surface DC. For example, if (e.g., when) the ink is ejected to the outside of the inkjet head IH through the plurality of nozzles NZ, a portion of the ink may remain on the ejection surface DC without being ejected onto the substrate. For example, a portion of the ink may remain on a first coating layer (e.g., a first coating layer CF1 of FIG. 6) without being ejected onto the substrate. Accordingly, after the ink is ejected to the outside of the inkjet head IH through the plurality of nozzles NZ, a process (or step (e.g., act or task)) of removing the ink remaining on the ejection surface DC may be desired or required.

In one or more embodiments, the ink remaining on the ejection surface DC may be removed in a contact manner. The contact manner may refer to a method of removing the ink remaining on the ejection surface DC by contacting a specific object with the ejection surface DC. For example, as illustrated in FIGS. 3 and 4, the ink remaining on the ejection surface DC may be removed by contacting a wiper WP with the ejection surface DC. For example, the ink remaining on the ejection surface DC may be removed in a contact manner through a blotting process.

In one or more embodiments, contact between the ejection surface DC and the wiper WP may refer to that a first coating layer (e.g., a first coating layer CF1 of FIG. 6) on the ejection surface DC and the wiper WP directly contact each other.

The inkjet head IH may be to move to contact the wiper WP. For example, the inkjet head IH may be to move such that the ejection surface DC contacts the wiper WP. For example, as illustrated in FIGS. 3 and 4, the inkjet head IH may be to move in a direction opposite to the third direction DR3 to allow the ejection surface DC and the wiper WP to contact each other. However, embodiments of the present disclosure are not limited thereto, and the ejection surface DC and the wiper WP may contact each other by moving the wiper WP in the third direction DR3.

The inkjet head IH may be to reciprocate while the ejection surface DC and the wiper WP contact with each other. For example, as illustrated in FIG. 4, the inkjet head IH may be to reciprocate in the first direction DR1 and a direction opposite to the first direction DR1 while the ejection surface DC and the wiper WP contact with each other. Accordingly, the ink remaining on the ejection surface DC may be removed. However, embodiments of the present disclosure are not limited thereto, and the wiper WP may also be to reciprocate while the ejection surface DC and the wiper WP contact with each other.

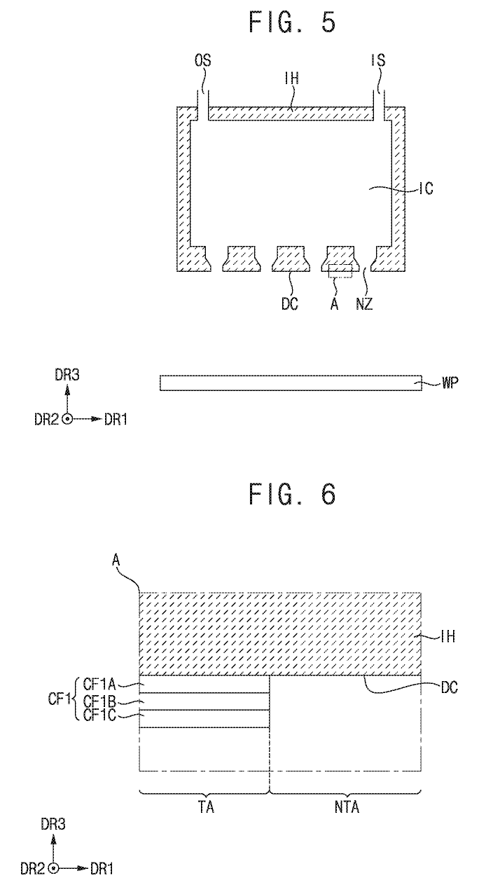

As illustrated in FIG. 5, after the ink remaining on the ejection surface DC is removed, the inkjet head IH may move in the third direction DR3.

FIGS. 6, 7, and 8 are cross-sectional views illustrating steps (e.g., acts or tasks) in which a first coating layer on an ejection surface of the inkjet head of FIG. 5 is removed.

Referring to FIG. 6, a first coating layer CF1 may be located or arranged on the ejection surface DC. The first coating layer CF1 may be coated on the ejection surface DC to perform a function of minimizing or reducing an amount of the ink remaining on the ejection surface DC or to prevent the inkjet head IH from being worn or damaged (or reduce a degree to or occurrence of which the inkjet head IH is worn or damaged). For example, the first coating layer CF1 may be located or arranged over an entire area of the ejection surface DC.

In one or more embodiments, the first coating layer CF1 may include a plurality of layers. For example, as illustrated in FIG. 6, the first coating layer CF1 may include a 1-1 coating layer CF1A, a 1-2 coating layer CF1B, and a 1-3 coating layer CF1C. The 1-1 coating layer CF1A may be located or arranged on the ejection surface DC. For example, the 1-1 coating layer CF1A may be a coating layer coated on a surface of the inkjet head IH. The 1-2 coating layer CF1B may be located or arranged on the 1-1 coating layer CF1A. The 1-3 coating layer CF1C may be located or arranged on the 1-2 coating layer CF1B. In one or more embodiments, the 1-1 coating layer CF1A, the 1-2 coating layer CF1B, and the 1-3 coating layer CF1C may include different materials from each other. If (e.g., when) the first coating layer CF1 includes the 1-1 coating layer CF1A, the 1-2 coating layer CF1B, and the 1-3 coating layer CF1C, the ink remaining on the ejection surface DC may refer to an ink remaining on a surface of the 1-3 coating layer CF1C opposite to (e.g., facing) the substrate.

The 1-1 coating layer CF1A may include an organic film. For example, the 1-1 coating layer CF1A may include an organic film including carbon. However, embodiments of the present disclosure are not limited thereto, and the 1-1 coating layer CF1A may include other types (kinds) of materials.

The 1-2 coating layer CF1B may include a wear-resistant material. For example, the 1-2 coating layer CF1B may include silicon oxycarbide (SiOC), silicon nitride (SiN), silicon boron nitride (SiBN), silicon oxynitride carbide (SiOCN), silicon dioxide (SiO₂), silicon oxynitride (SiON), aluminum oxide (Al₂O₃), silicon carbide (SiC), titanium nitride (TiN), titanium aluminum nitride (TiAlN), aluminum chromium nitride (AlCrN), and/or the like. These materials may be utilized alone or in combination. However, embodiments of the present disclosure are not limited thereto, and the 1-2 coating layer CF1B may include other types (kinds) of materials.

The 1-3 coating layer CF1C may include a liquid-repellent material. For example, the 1-3 coating layer CF1C may include a fluorine-based material, a silicon-based material, and/or the like. These materials may be utilized alone or in combination. Examples of the fluorine-based material may include fluororesin, a fluorocarbon film, a fluoropolymer, and/or the like. These materials may be utilized alone or in combination. An example of the silicon-based material may include a silicone resin and/or the like. However, embodiments of the present disclosure are not limited thereto, and the 1-3 coating layer CF1C may include a liquid-repellent material other than those described herein. An amount of the ink remaining on the ejection surface DC may be minimized or reduced as the first coating layer CF1 includes the 1-3 coating layer CF1C.

In one or more embodiments, the first coating layer CF1 may include three coating layers. For example, the first coating layer CF1 may include a 1-1 coating layer CF1A, a 1-2 coating layer CF1B, and a 1-3 coating layer CF1C. However, embodiments of the present disclosure are not limited thereto, and in one or more embodiments, the first coating layer CF1 may include four or more coating layers including different materials from each other.

As described in one or more embodiments with reference to FIGS. 3 and 4, the ink remaining on the ejection surface DC may be removed in the contact manner through the blotting process. For example, the ink remaining on the ejection surface DC may be removed by reciprocating the inkjet head IH while the ejection surface DC and the wiper (e.g., the wiper WP of FIG. 3) contact each other. For example, the ink remaining on the first coating layer CF1 may be removed by reciprocating the inkjet head IH while the first coating layer CF1 and the wiper contact each other.

Accordingly, wear may occur on the first coating layer CF1 in a reciprocating direction of the inkjet head IH. For example, a portion of the first coating layer CF1 may be removed. For example, as illustrated in FIG. 6, a first area NTA in which the first coating layer CF1 is removed and a second area TA in which the first coating layer CF1 remains without being removed may be formed on the ejection surface DC. A positional relationship between the first area NTA and the second area TA as illustrated in FIG. 6 is merely an example, and the positional relationship between the first area NTA and the second area TA may vary according to one or more embodiments.

The first coating layer CF1 may not be located or arranged in the first area NTA. As the blotting process proceeds as the wiper contacts the ejection surface DC, the first area NTA in which the first coating layer CF1 is removed may be formed. For example, the 1-1 coating layer CF1A, the 1-2 coating layer CF1B, and the 1-3 coating layer CF1C may not be located or arranged in the first area NTA. The first coating layer CF1 may be located or arranged in the second area TA. For example, the 1-1 coating layer CF1A, the 1-2 coating layer CF1B, and the 1-3 coating layer CF1C may be located or arranged in the second area TA. Even if (e.g., when) the blotting process proceeds as the wiper contacts the ejection surface DC, the second area TA in which the first coating layer CF1 is not removed may be formed. The first area NTA may be an area in which the first coating layer CF1 is worn (or lost).

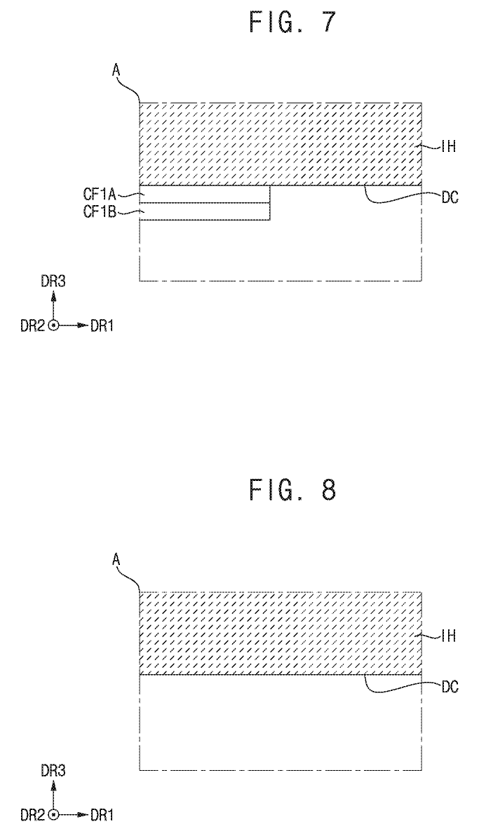

Referring to FIGS. 7 and 8, the first coating layer CF1 may be removed. For example, the first coating layer CF1 in the second area TA may be removed. In one or more embodiments, the 1-3 coating layer CF1C may be removed through an ashing process. For example, the 1-3 coating layer CF1C may be removed through an oxygen (O₂) ashing process. However, embodiments of the present disclosure are not limited thereto, and the 1-3 coating layer CF1C may be removed by one or more suitable methods.

As illustrated in FIG. 7, after the 1-3 coating layer CF1C is removed, each of the 1-1 coating layer CF1A and the 1-2 coating layer CF1B may be removed. In one or more embodiments, each of the 1-1 coating layer CF1A and the 1-2 coating layer CF1B may be removed through a laser trimming process. However, embodiments of the present disclosure are not limited thereto, and each of the 1-1 coating layer CF1A and the 1-2 coating layer CF1B may be removed by one or more suitable methods. For example, each of the 1-1 coating layer CF1A and the 1-2 coating layer CF1B may be removed through a dry etching process.

FIGS. 6, 7, and 8 illustrate an example in which the first area NTA, in which the first coating layer CF1 is removed, and the second area TA, in which the first coating layer CF1 remains, are formed on the ejection surface DC, but embodiments of the present disclosure are not limited thereto. For example, through the blotting process, a third area in which only the 1-3 coating layer CF1C among the 1-1 coating layer CF1A, the 1-2 coating layer CF1B, and the 1-3 coating layer CF1C is removed may be formed. In one or more embodiments, through the blotting process, a fourth area in which the 1-3 coating layer CF1C and the 1-2 coating layer CF1B among the 1-1 coating layer CF1A, the 1-2 coating layer CF1B, and the 1-3 coating layer CF1C are removed may be formed. In this case, the 1-1 coating layer CF1A and the 1-2 coating layer CF1B remaining in the third area without being removed may be removed through a laser trimming process and/or the like, and the 1-1 coating layer CF1A remaining in the fourth area without being removed may also be removed through a laser trimming process and/or the like. For example, through the processes as illustrated in FIGS. 6, 7, and 8, all coating layers on the ejection surface DC may be removed.

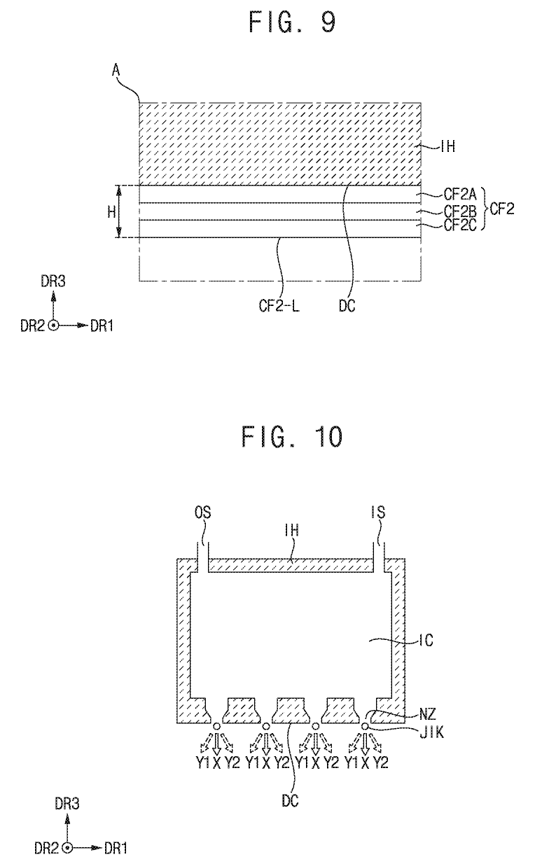

FIG. 9 is a cross-sectional view illustrating a step (e.g., an act or a task) in which a second coating layer is formed on an ejection surface of the inkjet head of FIG. 8. FIG. 10 is a cross-sectional view illustrating a step in which ink is ejected by the inkjet head of FIG. 9.

Referring to FIG. 9, a second coating layer CF2 may be formed on the ejection surface DC. The second coating layer CF2 may be coated on the ejection surface DC to perform a function of minimizing or reducing an amount of ink remaining on the ejection surface DC or to prevent the inkjet head IH from being worn or damaged (or reduce a degree to or occurrence of which the inkjet head IH is worn or damaged). For example, the second coating layer CF2 and the first coating layer (e.g., the first coating layer CF1 of FIG. 6) may be to perform substantially the same function, but embodiments of the present disclosure are not limited thereto. For example, the second coating layer CF2 may be formed over an entire area of the ejection surface DC.

In one or more embodiments, the second coating layer CF2 may include a plurality of layers. For example, as illustrated in FIG. 9, the second coating layer CF2 may include a 2-1 coating layer CF2A, a 2-2 coating layer CF2B, and a 2-3 coating layer CF2C. The 2-1 coating layer CF2A may be located or arranged on the ejection surface DC. For example, the 2-1 coating layer CF2A may be a layer coated on a surface of the inkjet head IH. The 2-2 coating layer CF2B may be located or arranged on the 2-1 coating layer CF2A. The 2-3 coating layer CF2C may be located or arranged on the 2-2 coating layer CF2B. In one or more embodiments, the 2-1 coating layer CF2A, the 2-2 coating layer CF2B, and the 2-3 coating layer CF2C may include different materials from each other.

The 2-1 coating layer CF2A may include a wear-resistant material. In one or more embodiments, the 2-1 coating layer CF2A may include a compound containing aluminum (Al), titanium (Ti), and/or the like. For example, the 2-1 coating layer CF2A may include silicon oxycarbide (SiOC), silicon nitride (SiN), silicon boron nitride (SiBN), silicon oxynitride carbide (SiOCN), silicon dioxide (SiO₂), silicon oxynitride (SiON), aluminum oxide (Al₂O₃), silicon carbide (SiC), titanium nitride (TiN), titanium aluminum nitride (TiAlN), aluminum chromium nitride (AlCrN), and/or the like. These materials may be utilized alone or in combination. However, embodiments of the present disclosure are not limited thereto, and the 2-1 coating layer CF2A may include other types (kinds) of materials.

The 2-2 coating layer CF2B may include an adhesive material. For example, the 2-2 coating layer CF2B may include an acrylic adhesive, a silicone adhesive, a urethane adhesive, and/or the like. These materials may be utilized alone or in combination. In one or more embodiments, the 2-2 coating layer CF2B may further include inorganic particles, such as silicon dioxide (SiO₂), titanium dioxide (TiO₂), and/or the like to exhibit improved or enhanced strength. However, embodiments of the present disclosure are not limited thereto, and the 2-2 coating layer CF2B may include other types (kinds) of materials.

The 2-3 coating layer CF2C may include a liquid-repellent material. For example, the 2-3 coating layer CF2C may include a fluorine-based material, a silicon-based material, and/or the like. These materials may be utilized alone or in combination. Examples of the fluorine-based material may include fluororesin, a fluorocarbon film, a fluoropolymer, and/or the like. These materials may be utilized alone or in combination. An example of the silicon-based material may include a silicone resin, and/or the like. However, embodiments of the present disclosure are not limited thereto, and the 2-3 coating layer CF2C may include a liquid-repellent material other than those described herein. As the second coating layer CF2 includes the 2-3 coating layer CF2C, an amount of the ink remaining on the ejection surface DC may be minimized or reduced.

As described in one or more embodiments with reference to FIGS. 6, 7, and 8, the first coating layer (e.g., the first coating layer CF1 of FIG. 6) may be completely (e.g., substantially completely) removed before the second coating layer CF2 is formed on the ejection surface DC. For example, the first coating layer may be removed over an entire area of the ejection surface DC before the second coating layer CF2 is formed on the ejection surface DC. Accordingly, the second coating layer CF2 may be formed on the ejection surface DC without including a step over an entire area of the ejection surface DC. For example, a distance H between a lower surface CF2-L of the second coating layer CF2 and the ejection surface DC may be substantially uniform over an entire area of the ejection surface DC. The lower surface CF2-L of the second coating layer CF2 may be a lower surface of a component (or, layer) at bottom of the second coating layer CF2. For example, as illustrated in FIG. 9, the lower surface CF2-L of the second coating layer CF2 may be a lower surface of the 2-3 coating layer CF2C. The lower surface CF2-L of the second coating layer CF2 may be a surface opposite to (e.g., facing) the substrate (e.g., the substrate SUB of FIG. 1).

Referring further to FIG. 10, as the second coating layer CF2 is formed on the ejection surface DC without including a step over an entire area of the ejection surface DC, the ink JIK may be ejected in a direction X normal (e.g., substantially perpendicular) to the ejection surface DC. The direction X normal (e.g., substantially perpendicular) to the ejection surface DC may be a direction parallel to the third direction DR3. For example, as the first coating layer is completely (e.g., substantially completely) removed, the second coating layer CF2 may be formed on the ejection surface DC without including a step over an entire area of the ejection surface DC, thereby preventing the ink JIK from being ejected in oblique directions Y1 and Y2 (or reduce a degree to or occurrence of which the ink JIK is ejected in oblique directions Y1 and Y2) with respect to the ejection surface DC. Accordingly, ink ejection characteristics of the inkjet head IH may be improved or enhanced. The oblique directions Y1 and Y2 with respect to the ejection surface DC may be directions that are not parallel to the third direction DR3 and cross the third direction DR3. If (e.g., when) a step is formed in the second coating layer CF2, a portion of the ink JIK may be ejected in the oblique directions Y1 and Y2.

The ink (e.g., the ink IK of FIG. 2) ejected from the inkjet head IH in a state in which the first coating layer is located or arranged on the ejection surface DC may be referred to as first ink, and the ink JIK ejected from the inkjet head IH in a state in which the second coating layer CF2 is located or arranged on the ejection surface DC may be referred to as second ink.

Series of processes as described herein with reference to FIGS. 3, 4, 5, 6, 7, 8, and 9 may be repeated. For example, after the ink JIK is ejected onto the substrate, a portion of the second coating layer CF2 may also be removed through a blotting process. After the blotting process, the second coating layer CF2 remaining on the ejection surface DC may be entirely (e.g., substantially entirely) removed. Accordingly, a step may not be formed in a new coating layer that is subsequently coated on the ejection surface DC.

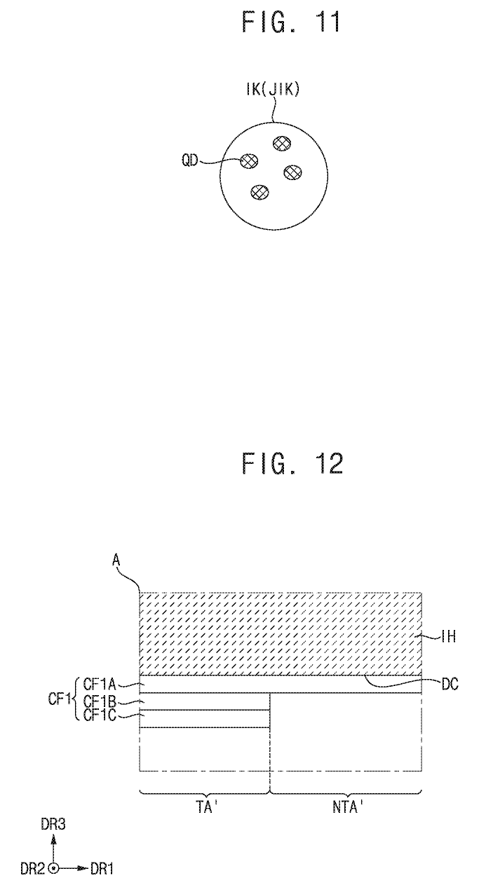

FIG. 11 is a diagram schematically illustrating an ink.

Referring to FIG. 11, in one or more embodiments, the ink IK or JIK may include a quantum dot QD. The quantum dot QD may be to emit light by stimulation of light. As described in one or more embodiments, the display device may be an organic light-emitting display device. In this case, the display device may include a light-emitting element and a color conversion layer on the light-emitting element. The color conversion layer may include the quantum dot QD. The color conversion layer may be formed by ejecting the ink IK or JIK including the quantum dot QD onto the substrate.

As described in one or more embodiments, the display device may be a quantum dot light-emitting display device. In this case, the display device may include a light-emitting element. The light-emitting element may include a light-emitting layer including a quantum dot QD. The light-emitting layer may be formed by ejecting the ink IK or JIK including the quantum dot QD onto the substrate.

For example, the quantum dot QD may include an II-VI group semiconductor compound, an III-VI group semiconductor compound, an III-V group semiconductor compound, an IV-VI group semiconductor compound, an IV group element, a compound including an IV group element, an I-III-VI group semiconductor compound, and/or the like. These materials may be utilized alone or in combination with each other.

The II-VI group semiconductor compound may include a binary compound, such as CdS, CdSe, CdTe, ZnS, ZnSe, ZnTe, ZnO, HgS, HgSe, HgTe, MgS, MgSe, and/or the like; a ternary compound, such as CdSeS, CdSeTe, CdSTe, ZnSeS, ZnSeTe, ZnSTe, HgSeS, HgSeTe, HgSTe, CdZnS, CdZnSe,CdZnTe, CdHgS, CdHgSe, CdHgTe, HgZnS, HgZnSe, HgZnTe MgZnS, MgZnSe, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; and a (e.g., any suitable) combination of the compounds as described herein.

The III-VI group semiconductor compound may include a binary compound, such as In₂S₃, Ga₂S₃, and/or the like; a ternary compound, such as InGaS₃, InGaSe₃ and/or the like; and a (e.g., any suitable) combination of the compounds as described herein.

The III-V group semiconductor compound may include a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAs, AlPSb, InAsP, InGaP, InGaAs, InAlP, InNP, InNAs, InNSb, InPAs, InPSb, and/or the like; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; and a (e.g., any suitable) combination of the compounds as described herein. The III-V group semiconductor compound may further include a group II metal (e.g., InZnP and/or the like).

The IV-VI group semiconductor compound may include a binary compound, such as SnS, SnSe, SnTe, PbS, PbSe, PbTe, and/or the like; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; and a (e.g., any suitable) combination of the compounds as described herein.

The IV group element and the compound including the IV group element may include a unary compound, such as Si and/or Ge, a binary compound, such as SiC, SiGe, and/or the like; and a (e.g., any suitable) combination of the compounds as described herein.

The I-III-VI group semiconductor compound may include a ternary compound, such as AgInS, AgInS₂, CuInS, CuInS₂, CuGaO₂, AgGaO₂, AgAlO₂,and/or the like; and a (e.g., any suitable) combination of the compounds as described herein. The I-III-VI group semiconductor compound may further include an II group element. For example, the I-III-VI group semiconductor compound may include a quaternary compound, such as CuInZnS.

As illustrated in FIG. 11, if (e.g., when) the ink IK or JIK includes particles, such as the quantum dot QD, a probability that a portion of a coating layer (e.g., the first coating layer CF1 of FIG. 6 or the second coating layer CF2 of FIG. 9) on the ejection surface (e.g., the ejection surface DC of FIG. 2) is removed may increase if (e.g., when) the ink IK or JIK remaining on the ejection surface is removed through a blotting process. For example, if (e.g., when) the ink IK or JIK includes particles, such as the quantum dot QD, a probability that a portion of the coating layer is removed due to friction between the particles and the coating layer may increase. For example, as illustrated in FIG. 6, a probability that the first area (e.g., the first area NTA of FIG. 6) and the second area (e.g., the second area TA of FIG. 6) are formed may increase. Accordingly, if (e.g., when) the ink IK or JIK includes particles, such as the quantum dot QD, a process of removing the coating layer on the ejection surface, as described in more detail with reference to FIGS. 6, 7, and 8, may be desired or required.

However, embodiments of the present disclosure are not limited thereto, and in one or more embodiments, the ink IK or JIK may not include (e.g., may exclude) particles, such as the quantum dot QD. Even in this case, if (e.g., when) the ink IK or JIK remaining on the ejection surface is removed through the blotting process, a portion of the coating layer (e.g., the first coating layer CF1 of FIG. 6 or the second coating layer CF2 of FIG. 9) on the ejection surface may be removed. Accordingly, a process of removing the coating layer on the ejection surface, as described in more detail with reference to FIGS. 6, 7, and 8, may be desired or required.

FIGS. 12, 13, and 14 are cross-sectional views illustrating steps (e.g., steps or tasks) in which a first coating layer on an ejection surface of the inkjet head of FIG. 5 is removed.

A step (e.g., act or task) of removing the first coating layer CF1 as illustrated in FIGS. 12, 13, and 14 may differ from the step (e.g., act or task) of removing the first coating layer CF1 as described with reference to FIGS. 6, 7, and 8 in that only the 1-2 coating layer CF1B and the 1-3 coating layer CF1C are removed through the blotting process, and only the 1-2 coating layer CF1B and the 1-3 coating layer CF1C are removed through a laser trimming process and/or the like. Accordingly, redundant descriptions may not be provided or simplified.

Referring to FIGS. 12, 13, and 14, the ink remaining on the ejection surface DC may be removed in the contact manner through the blotting process. Accordingly, a portion of the first coating layer CF1 may be removed. For example, as illustrated in FIG. 12, the 1-1 coating layer CF1A may not be removed, and a portion of each of the 1-2 coating layer CF1B and the 1-3 coating layer CF1C may be removed. For example, a first area NTA` in which each of the 1-2 coating layer CF1B and the 1-3 coating layer CF1C is removed and a second area TA` in which the 1-2 coating layer CF1B and the 1-3 coating layer CF1C remain without being removed may be formed on the ejection surface DC. A positional relationship between the first area NTA` and the second area TA` as illustrated in FIG. 12 is merely an example, and the positional relationship between the first area NTA` and the second area TA` may vary according to one or more embodiments.

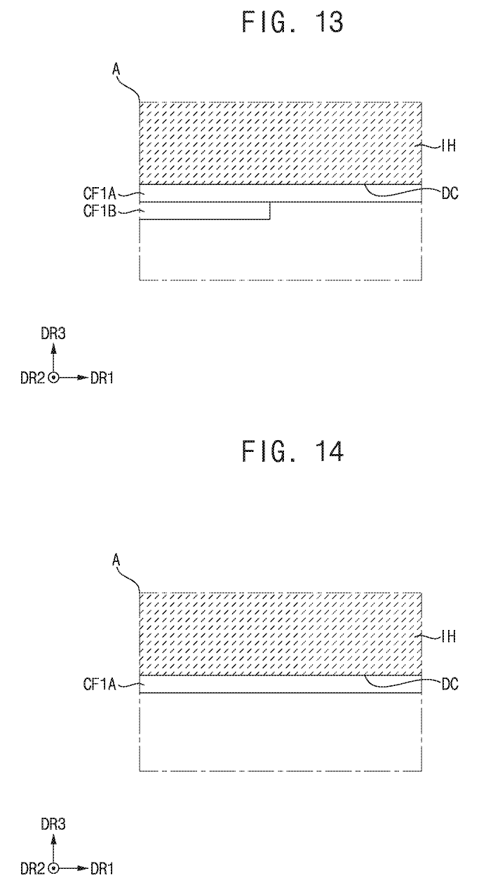

As illustrated in FIG. 13, the 1-3 coating layer CF1C may be removed. In one or more embodiments, the 1-3 coating layer CF1C may be removed through an ashing process. For example, the 1-3 coating layer CF1C may be removed through an oxygen (O₂) ashing process. However, embodiments of the present disclosure are not limited thereto, and the 1-3 coating layer CF1C may be removed by one or more suitable methods.

As illustrated in FIG. 14, after the 1-3 coating layer CF1C is removed, the 1-2 coating layer CF1B may be removed. In one or more embodiments, the 1-2 coating layer CF1B may be removed through a laser trimming process. However, embodiments of the present disclosure are not limited thereto, and the 1-2 coating layer CF1B may also be removed by one or more suitable methods, such as a dry etching process.

As described in one or more embodiments, the 1-1 coating layer CF1A may not be removed. For example, through the laser trimming process, only the 1-2 coating layer CF1B among the 1-1 coating layer CF1A and the 1-2 coating layer CF1B may be selectively removed. If (e.g., when) a portion of layer in the first coating layer CF1 is not removed on the ejection surface DC through the blotting process, there may be no need or desire to remove the portion of the layer in the first coating layer CF1 through the laser trimming process and/or the like. For example, if (e.g., when) the 1-1 coating layer CF1A is not removed on the ejection surface DC through the blotting process, the 1-1 coating layer CF1A may not need to be removed through the laser trimming process and/or the like.

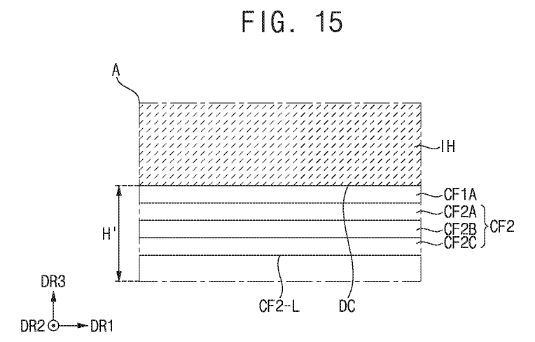

Referring further to FIG. 15, even if (e.g., when) the 1-1 coating layer CF1A is not removed on the ejection surface DC, the second coating layer CF2 formed on the 1-1 coating layer CF1A may not include (e.g., may exclude) a step (e.g., without introducing a step or elevation change). For example, a distance H` between a lower surface CF2-L of the second coating layer CF2 and the ejection surface DC may be substantially uniform over the entire area of the ejection surface DC. The lower surface CF2-L of the second coating layer CF2 may be an upper surface of a component (or layer) at bottom of the second coating layer CF2. For example, as illustrated in FIG. 15, the lower surface of the second coating layer CF2 may be a lower surface CF2-L of the 2-3 coating layer CF2C.

As the second coating layer CF2 is formed on the first coating layer CF1 without including any step (e.g., without introducing a step or elevation change) over the entire area of the ejection surface DC, the ink (e.g., the ink JIK of FIG. 10) may be ejected in the direction (e.g., the direction X of FIG. 10) that is normal (e.g., substantially perpendicular) to the ejection surface DC.

One or more embodiments of the present disclosure may be applied to one or more suitable inkjet apparatuses. For example, one or more embodiments of the present disclosure may be applicable to one or more suitable inkjet apparatuses to eject an ink onto a target object. For example, one or more embodiments of the present disclosure may be applicable to one or more suitable inkjet apparatuses to eject the ink onto a substrate in a display device, an electronic device, and/or the like.

One or more embodiments of the present disclosure provide an electronic device, wherein the electronic device includes a display device. The display device may be formed by the method as described in one or more embodiments.

A patterning device, a developer composition manufacturing device, a display device being formed by the same, an electronic device including the display device, and/or any other relevant devices or components according to one or more embodiments of the present disclosure may be implemented utilizing any suitable hardware, firmware (e.g., an application-specific integrated circuit), software, or a combination of software, firmware, and hardware. For example, the one or more suitable components of the device may be formed or arranged on one integrated circuit (IC) chip or on separate IC chips. Further, the one or more suitable components of the device may be implemented on a flexible printed circuit film, a tape carrier package (TCP), a printed circuit board (PCB) or formed or arranged on one substrate. Further, the one or more suitable components of the device may be a process or thread, running on one or more processors, in one or more computing devices, executing computer program instructions and interacting with other system components to perform the one or more suitable functionalities as described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the present disclosure.

The foregoing is illustrative of one or more embodiments of the present disclosure and is not to be construed as limiting thereof. Although certain embodiments of the present disclosure have been described, those skilled in the art will readily appreciate that one or more suitable modifications may be possible in one or more embodiments without materially departing from the novel teachings and aspects of the present disclosure. Accordingly, all such modifications are intended to be included within the scope of the present disclosure as claimed in the claims. Therefore, it is to be understood that the foregoing is illustrative of one or more suitable embodiments and is not to be construed as limited to the specific embodiments disclosed, and that modifications to the disclosed embodiments, as well as one or more embodiments, are intended to be included within the scope of the appended claims and equivalents thereof.

What is claimed is:

1. A method,
wherein the method is a method of forming a coating layer on an inkjet head,
the method comprising:
removing ink remaining on an ejection surface of the inkjet head;
removing a first coating layer on the ejection surface of the inkjet head; and
forming a second coating layer on the ejection surface of the inkjet head.

2. The method as claimed in claim 1, wherein the removing of the ink remaining on the ejection surface of the inkjet head comprises removing the ink remaining on the ejection surface of the inkjet head in a contact manner through a blotting process.

3. The method as claimed in claim 2, wherein a portion of the first coating layer on the ejection surface of the inkjet head is removed by the blotting process.

4. The method as claimed in claim 2, wherein a first area in which the first coating layer is removed and a second area in which the first coating layer remains are on the ejection surface of the inkjet head by the blotting process.

5. The method as claimed in claim 4, wherein the first coating layer remaining in the second area is removed through the removing of the first coating layer.

6. The method as claimed in claim 1, wherein the first coating layer comprises:
a 1-1 coating layer on the ejection surface of the inkjet head;
a 1-2 coating layer on the 1-1 coating layer; and
a 1-3 coating layer on the 1-2 coating layer and comprising a liquid-repellent material.

7. The method as claimed in claim 6, wherein the removing of the first coating layer comprises removing the 1-3 coating layer through an ashing process.

8. The method as claimed in claim 7, wherein the removing of the first coating layer further comprises removing the 1-1 coating layer and the 1-2 coating layer through a laser trimming process.

9. The method as claimed in claim 8, wherein a distance between a lower surface of the second coating layer and the ejection surface of the inkjet head is substantially uniform over an entire area of the ejection surface of the inkjet head by the removing of the 1-3 coating layer through the ashing process and the removing of the 1-1 coating layer and the 1-2 coating layer through the laser trimming process.

10. The method as claimed in claim 6, wherein a first area in which the 1-1 coating layer, the 1-2 coating layer, and the 1-3 coating layer are removed on the ejection surface of the inkjet head and a second area in which the 1-1 coating layer, the 1-2 coating layer, and the 1-3 coating layer remain are formed by the blotting process.

11. The method as claimed in claim 1, wherein the second coating layer comprises:
a 2-1 coating layer on the ejection surface of the inkjet head and comprising a wear-resistant material;
a 2-2 coating layer on the 2-1 coating layer; and
a 2-3 coating layer on the 2-2 coating layer and comprising a liquid-repellent material.

12. The method as claimed in claim 11, wherein the 2-1 coating layer comprises at least one selected from the group consisting of aluminum oxide (Al₂O₃), silicon carbide (SiC), titanium nitride (TiN), titanium aluminum nitride (TiAlN), and aluminum chromium nitride (AlCrN).

13. A method,
wherein the method is a method of forming a coating layer on an inkjet head,
the method comprising:
removing ink remaining on an ejection surface of the inkjet head through a blotting process;
removing a 1-2 coating layer and a 1-3 coating layer from a first coating layer, the first coating layer comprising a 1-1 coating layer on the ejection surface of the inkjet head, the 1-2 coating layer on the 1-1 coating layer, and the 1-3 coating layer on the 1-2 coating layer; and
forming a second coating layer on the 1-1 coating layer.

14. The method as claimed in claim 13, wherein the removing of the 1-2 coating layer and the 1-3 coating layer from the first coating layer comprises removing the 1-3 coating layer through an ashing process and removing the 1-2 coating layer through a laser trimming process, and
a distance between a lower surface of the second coating layer and the ejection surface of the inkjet head is substantially uniform over an entire area of the ejection surface of the inkjet head by the removing of the 1-3 coating layer through the ashing process and the removing of the 1-1 coating layer and the 1-2 coating layer through the laser trimming process.

15. A method,
wherein the method is a method of ejecting ink utilizing an inkjet head,
the method comprising:
ejecting first ink utilizing the inkjet head;
removing the first ink remaining on an ejection surface of the inkjet head;
removing a first coating layer on the ejection surface of the inkjet head;
forming a second coating layer on the ejection surface of the inkjet head; and
ejecting second ink utilizing the inkjet head.

16. The method as claimed in claim 15, wherein the removing of the first ink remaining on the ejection surface of the inkjet head comprises removing the first ink remaining on the ejection surface of the inkjet head in a contact manner through a blotting process.

17. The method as claimed in claim 16, wherein a first area in which the first coating layer is removed and a second area in which the first coating layer remains are on the ejection surface of the inkjet head by the blotting process.

18. The method as claimed in claim 17, wherein the first coating layer remaining in the second area is removed through the removing of the first coating layer.

19. The method as claimed in claim 15, wherein the first coating layer comprises,
a 1-1 coating layer on the ejection surface of the inkjet head;
a 1-2 coating layer on the 1-1 coating layer; and
a 1-3 coating layer on the 1-2 coating layer and comprising a liquid-repellent material,
the removing of the first coating layer comprises removing the 1-3 coating layer through an ashing process and removing the 1-2 coating layer through a laser trimming process, and
a distance between a lower surface of the second coating layer and the ejection surface of the inkjet head is substantially uniform over an entire area of the ejection surface of the inkjet head by the removing of the 1-3 coating layer through the ashing process and the removing of the 1-1 coating layer and the 1-2 coating layer through the laser trimming process.

20. The method as claimed in claim 19, wherein the second ink is ejected in a direction substantially perpendicular to the ejection surface by the removing of the 1-3 coating layer through the ashing process and the removing of the 1-1 coating layer and the 1-2 coating layer through the laser trimming process.
